(19) United States
(12) Patent Application Publication
(10) Pub. No.: US 2015/0060119 A1
(43) Pub. Date: Mar. 5, 2015

(54) CONDUCTIVE STRUCTURE AND MANUFACTURING METHOD THEREOF

(71) Applicant: National Tsing Hua University, Hsinchu City (TW)

(72) Inventors: Hao-Wu LIN, Zhubei City (TW); Kai-Ming CHIANG, Hsinchu City (TW); Jung-Hao CHANG, Hsinchu City (TW); Cheng-Yu HUANG, Taipei City (TW); Chih-Wei LU, Hsinchu City (TW)

(73) Assignee: National Tsing Hua University, Hsinchu City (TW)

(21) Appl. No.: 14/092,605

(22) Filed: Nov. 27, 2013

(30) Foreign Application Priority Data
Sep. 4, 2013 (TW) 102131901

(51) Int. Cl. H05K 1/09; H05K 3/46; H05K 1/02

(52) U.S. Cl. CPC H05K 1/097; H05K 1/0274; H05K 3/4664; H05K 2201/0326; H05K 2201/0302
USPC 174/257; 427/97.1; 427/97.6

(57) ABSTRACT

A conductive structure comprises a plurality of first nanowires and a plurality of second nanowires. The first nanowires extend along a first direction substantially. The second nanowires extend along a second direction substantially, and at least a part of the second nanowires electrical connect to the first nanowires. The included angle between the first and second directions is nonzero. A manufacturing method of the conductive structure is also disclosed.

### CROSS REFERENCE TO RELATED APPLICATIONS

This Non-provisional application claims priority under 35 U.S.C. §119(a) on Patent Application No(s). 102131901 filed in Taiwan, Republic of China on Sep. 4, 2013, the entire contents of which are hereby incorporated by reference.

### BACKGROUND OF THE INVENTION

1. Field of Invention

The present invention relates to a conductive structure and a manufacturing method thereof, and particularly to a transparent conductive nano-structure and a manufacturing method thereof.

2. Related Art

The common transparent conductive sheet is a conductive and light permeable coating or film, and it has been widely adopted in many applications such as displays, touch panels, solar cells, and other photoelectrical devices. In general, the transparent conductive sheet is mainly made of ITO. However, the vacuum sputtering equipment for ITO coating process is very expansive, so the manufacturing cost for the transparent conductive sheet is relatively higher.

The most potential substitutes for ITO include conductive polymers, metal nanowires, and carbon nanotubes. The transparent conductive sheets made of the above substitutes have equivalent or better light transparence and conductivity than the conventional ITO conductive sheets, and the duration thereof is much better.

Therefore, it is an important subject to provide a conductive structure that can form a transparent conductive sheet.

### SUMMARY OF THE INVENTION

In view of the foregoing subject, an objective of the present invention is to provide a conductive structure and a manufacturing method thereof.

To achieve the above objective, the present invention discloses a conductive structure including a plurality of first nanowires and a plurality of second nanowires. The first nanowires extend along a first direction substantially. The second nanowires extend along a second direction substantially, and at least a part of the second nanowires electrical connect to the first nanowires. The included angle between the first and second directions is nonzero.

In one embodiment, the nanowires are carbon nanotubes or metal nanowires.

In one embodiment, the conductive structure further comprises a plurality of conductive materials disposed at the junctions of parts of the first nanowires and the second nanowires, so that the first nanowires and the second nanowires are connected via the conductive materials.

In one embodiment, the conductive materials comprise ZnO.

To achieve the above objective, the present invention also discloses a manufacturing method of a conductive structure including the following steps of: coating a first suspension solution on a surface of a substrate, wherein the first suspension solution contains a plurality of first nanowires, and a coating method of the first suspension solution allows the first nanowires of the coated first suspension solution to extend along a first direction substantially; and coating a second suspension solution on the coated first suspension solution, wherein the second suspension solution contains a plurality of second nanowires, a coating method of the second suspension solution allows the second nanowires of the coated second suspension solution to extend along a second direction substantially, and at least a part of the second nanowires electrical connect to the first nanowires.

In addition, the present invention also discloses a manufacturing method of a conductive structure including the following steps of: coating a first suspension solution on a first surface of a first substrate, wherein the first suspension solution contains a plurality of first nanowires, and a coating method of the first suspension solution allows the first nanowires of the coated first suspension solution to extend along a first direction substantially; coating a second suspension solution on a second surface of a second substrate, wherein the second suspension solution contains a plurality of second nanowires, and a coating method of the second suspension solution allows the second nanowires of the coated second suspension solution to extend along a second direction substantially; and overlapping the first substrate and the second substrate, so that the first nanowires and the second nanowires are disposed on the first surface of the first substrate, wherein at least a part of the first nanowires and the second nanowires are electrically connected and form a nonzero included angle.

In one embodiment, the first nanowires and the second nanowires are carbon nanotubes or metal nanowires.

In one embodiment, the suspension solution is a solution of ethanol and/or water containing nanowires.

In one embodiment, the coating method of the suspension solution comprises blade coating, bar coating, rod coating, or slot die coating.

In one embodiment, the coating speed of the suspension solution is between 30 mm/s and 280 mm/s.

In one embodiment, the manufacturing method further comprises a step of heating a substrate to evaporate the solvents of the suspension solutions.

In one embodiment, the manufacturing method further comprises steps of: coating a colloid suspension solution containing a plurality of conductive materials on the surface; and annealing to form the conductive materials.

In one embodiment, the conductive materials comprise ZnO.

As mentioned above, to manufacturing the conductive structure of the invention, the suspension solution is coated along a specific direction by blade coating or bar coating and the coating speed is fixed, so that the nanowires in the suspension solution mostly extend along the same direction. Besides, it is possible to form two coatings in different directions on a single substrate, so that the manufactured conductive structure contains overlapped nanowires mainly in two directions. This configuration can form fewer nanowires in a unit area of the conductive structure, so that the conductive structure can have higher transparency and less raw material cost. Moreover, adding the conductive materials in the conductive structure can effectively reduce the junction resistance between the nanowires, thereby improving the conductivity thereof.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a schematic diagram showing a conductive structure according to an embodiment of the invention;

FIG. 1B is an enlarged view of the area A of the conductive structure as shown in FIG. 1A;

FIG. 2 is a sectional diagram of a conductive structure according to an embodiment of the invention;

FIG. 3 is a flow chart of a manufacturing method of the conductive structure according to an embodiment of the invention;

FIG. 4 is a graph showing the relationship between the amount of the wires and the arbitrary unit (a.u.) of the conductive structure according to an embodiment of the invention; and

FIG. 5 is a flow chart of another manufacturing method of the conductive structure according to an embodiment of the invention.

### DETAILED DESCRIPTION OF THE INVENTION

The present invention will be apparent from the following detailed description, which proceeds with reference to the accompanying drawings, wherein the same references relate to the same elements.

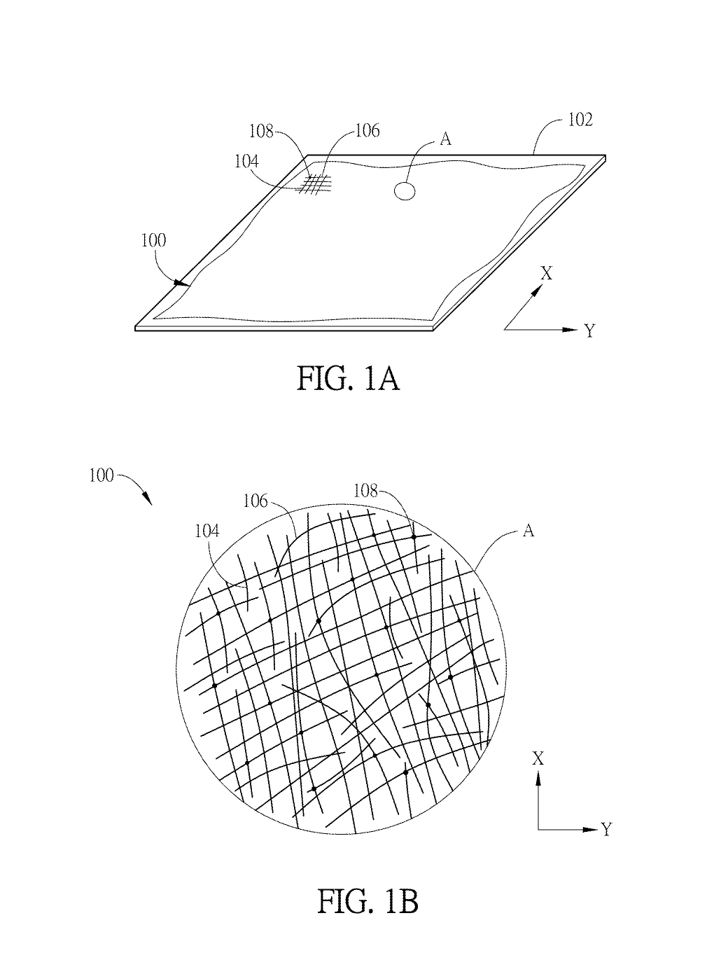

FIG. 1A is a schematic diagram showing a conductive structure 100 according to an embodiment of the invention, and FIG. 1B is an enlarged view of the area A of the conductive structure 100 as shown in FIG. 1A. Referring to FIGS. 1A and 1B, the conductive structure 100 is formed on a substrate 102 and includes a plurality of first nanowires 104 and a plurality of second nanowires 106. The first nanowires 104 extend along a first direction (e.g. the X direction) substantially. The second nanowires 106 extend along a second direction (e.g. the Y direction) substantially. A part of the first nanowires 104 and the second nanowires 106 are overlapped and contacted to form electrical connections. Since the first nanowires 104 and the second nanowires 106 are substantially disposed along the first direction X and the second direction Y, respectively, the included angle between the first and second nanowires 104 and 106 is nonzero. In particular, the included angle between the first and second directions is preferably about 90°. This configuration can form less nanowires in a unit area of the conductive structure, so that the conductive structure can have higher light transmittance (higher transparency) and less raw material (nanowires) cost.

In addition, the nanowires can be carbon nanotubes or metal nanowires made of conductive materials such as Au, Ag, Cu, or the likes. In some embodiments, to manufacture the conductive structure of the invention, the diameter of the nanowire is between 10 nm and 500 nm, the length thereof is between 5 μm and 500 μm, and the length-to-wide ratio is ranged from 10 to 50000.

As shown in FIGS. 1A and 1B, the conductive structure 100 may further include a plurality of conductive materials 108 disposed at the junctions of the first nanowires 104 and the second nanowires 106. The conductive materials 108 are located between the first nanowires 104 and the second nanowires 106, so that the first nanowires 104 can be connected to the second nanowires 106 via the conductive materials 108. In this embodiment, the conductive materials 108 are added to decrease the junction resistance between the first nanowires 104 and the second nanowires 106, thereby improving the conductivity of the conductive structure 100. In this embodiment, the conductive material can be any dielectric material capable of decreasing the junction resistance between the nanowires. To be noted, the conductive material may include ZnO or TiO₂, and this embodiment is, for example but not limited to, ZnO.

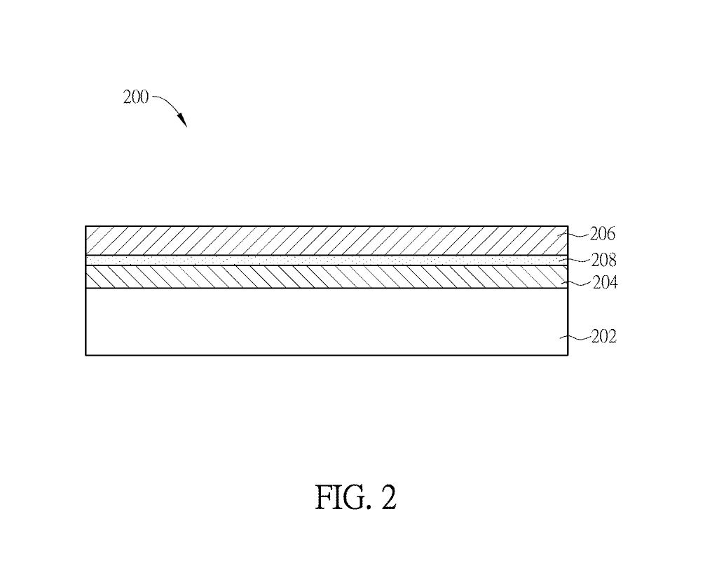

FIG. 2 is a sectional diagram of a conductive structure 200 according to an embodiment of the invention. Referring to FIG. 2, the conductive structure 200 is formed on a substrate 202 and is similar to the previously mentioned conductive structure 100. Different from the conductive structure 100, the conductive structure 200 includes a first nanowire layer 204 composed of the first nanowires 104 and a second nanowire layer 206 composed of the second nanowires 106. The first nanowire layer 204 and the second nanowire layer 206 are disposed on the substrate 202. Similarly, the first nanowires of the first nanowire layer 204 extend along the first direction, while the second nanowires of the second nanowire layer 206 extend along the second direction. A part of the first nanowires and the second nanowires are overlapped and contacted to form electrical connections. Since the first nanowires and the second nanowires are substantially disposed along the first direction and the second direction, respectively, the included angle between the first and second nanowires is nonzero. This configuration can form less nanowires in a unit area of the conductive structure, so that the conductive structure can have higher light transmittance (higher transparency) and less raw material (nanowires) cost.

As shown in FIG. 2, the conductive structure 200 further includes a conductive material layer 208 coated between the first nanowire layer 204 and the second nanowire layer 206. Thus, the first nanowire layer 204 can be connected to the second nanowire layer 206 via the conductive material layer 208. The conductive material layer 208 contains the conductive materials 108 as described in the above embodiment, so the detailed description thereof will be omitted.

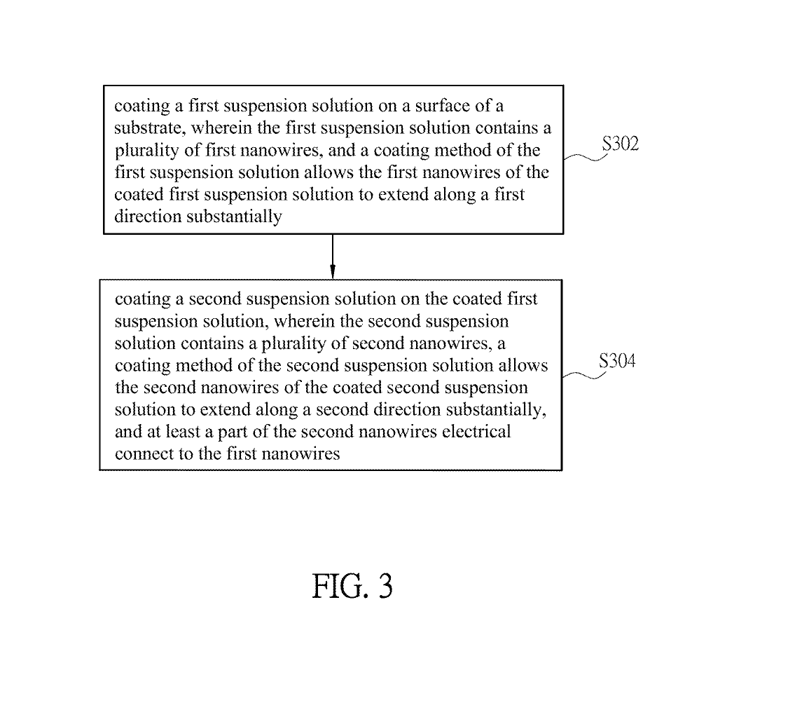

FIG. 3 is a flow chart of a manufacturing method of the conductive structure according to an embodiment of the invention. Referring to FIG. 3, the step S302 is to coat a first suspension solution on a surface of a substrate. The first suspension solution contains a plurality of first nanowires, and a coating method of the first suspension solution allows the first nanowires of the coated first suspension solution to extend along a first direction substantially. In some embodiments, the suspension solution is a solution of ethanol and/or water containing nanowires. Since the solvent of the suspension solution is easily evaporated and removed, so the nanowires can be deposited quickly. Next, the step S304 is to coat a second suspension solution on the coated first suspension solution so as to form second nanowires on the first nanowires. Similarly, the second suspension solution contains a plurality of second nanowires, and a coating method of the second suspension solution allows the second nanowires of the coated second suspension solution to extend along a second direction substantially. At least a part of the second nanowires electrical connect to the first nanowires. In other words, the manufacturing method of this embodiment is to coat the suspension solutions twice in different directions so as to form the desired conductive structure.

To be noted, the coating method of the suspension solution includes blade coating, bar coating, rod coating, or slot die coating, and the coating speed of the suspension solution is between 30 mm/s and 280 mm/s, and is preferably 100 mm/s. Since the coating direction is fixed at a single direction, the blade or other coating tools can apply shearing stresses to the nanowires during the coating process. Accordingly, the nanowires are forced to extend along the coating direction. Besides, since the coating speed is between 30 mm/s and 280 mm/s, the shearing stress can be applied to most nanowires to force them to extend along the coating direction. This process makes the nanowires substantially have directionality.

The definition of the above “directionality” is to determine whether the coating direction matches with the tangent direction of the center point of the nanowire. Assuming the included angle between the coating direction and the tangent direction of the center point of the nanowire is θ, the directionality can be determined according to the following equation:

$$S = \frac{3 {cos}^{2} θ - 1}{2} ,$$

−0.5≦S≦1. When S=−0.5, the coating direction is perpendicular to the tangent direction of the center point of the nanowire. When S=0, the nanowires have no directionality totally. When S=1, the nanowires have uniform directionality totally. When S=0.8, the nanowires are defined as having directionality. In this embodiment, the coating speed is controlled between 30 mm/s and 280 mm/s, so that the nanowires are disposed with directionality (S>0.8). Preferably, the coating speed is controlled at 100 mm/s to obtain that S=0.9, which means 100 mm/s is the better coating speed.

Expect for the above-mentioned coating methods, the nanowires can have directional arrangement by blowing method. In more detailed, an airflow toward the same direction is applied to blow the suspension solution containing nanowires. The airflow can apply a shearing stress to the nanowires so as to achieve the desired directionality of the nanowires. It can also be achieved by the Langmuir'Blodgett method.

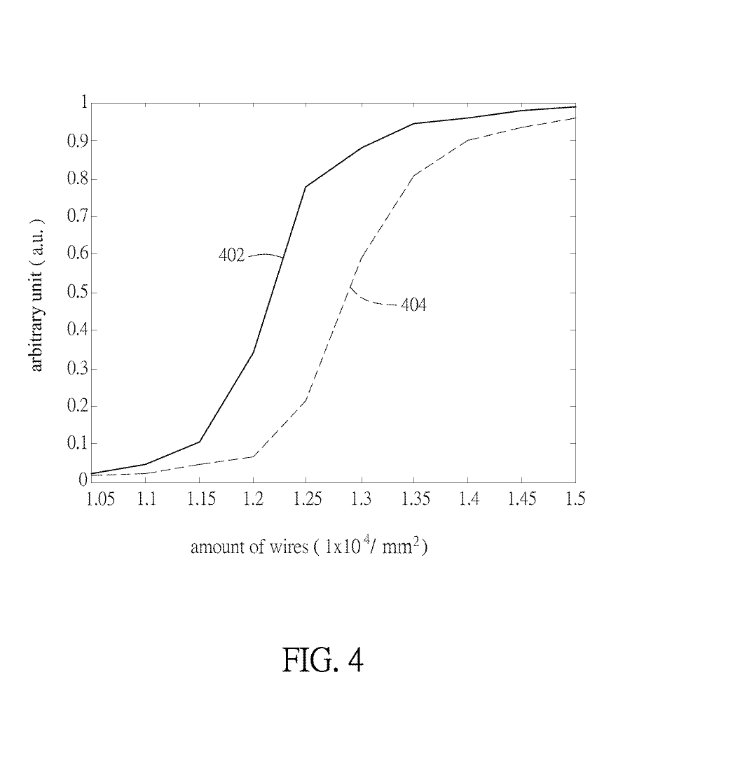

FIG. 4 is a graph showing the relationship between the amount of the wires and the arbitrary unit (a.u.) of the conductive structure according to an embodiment of the invention. As shown in FIG. 4, the horizontal axis indicates the amount of nanowires in unit area (1×10⁴/mm²), and the vertical axis indicates the arbitrary unit (a.u.), which represents the ratio of the electrically connected nanowires. In FIG. 4, the solid curve represents the characteristic of the conductive structure fabricated by the manufacturing method of the embodiment, and the dotted curve represents the characteristic of the conductive structure fabricated by spin coating. FIG. 4 shows that the conductive structure fabricated by the manufacturing method of the embodiment has higher arbitrary unit as the amount of the nanowires is the same. In other words, regarding to the same area of the conductive structure, the manufacturing method of the present embodiment can provide the conductive structure with the same or higher ratio of electrically connected nanowires by using fewer raw materials of nanowires. This feature can reduce the amount of nanowires, thereby decreasing the manufacturing cost.

In addition, the manufacturing method of the embodiment may further include a step of heating the substrate to evaporate the solvents of the suspension solutions. This heating step can speed the evaporation of the solvent (ethanol and/or water) in the suspension solution so as to deposit the nanowires, thereby decreasing the processing time.

To be noted, the manufacturing method of the embodiment may further include steps of: coating a colloid suspension solution containing a plurality of conductive materials on the surface; and annealing to form the conductive materials. Herein, the conductive materials include ZnO or TiO₂. In one embodiment, the colloid suspension solution is formed on the substrate by spin coating. In this embodiment, the colloid suspension solution is composed of Zn(CH₃COO)₂, 2-methoxyethanol and Ethanolamine. After coating the colloid suspension solution on the surface, the substrate is annealed for 5 minutes at 150° C. During the annealing process, the colloid suspension solution is reacted with oxygen to obtain ZnO nano-particles. Due to the surface tension effect, the ZnO nano-particles are naturally formed at the junctions between the nanowires. This structure can effectively reduce the junction resistance between the nanowires so as to increase the conductivity of the conductive structure.

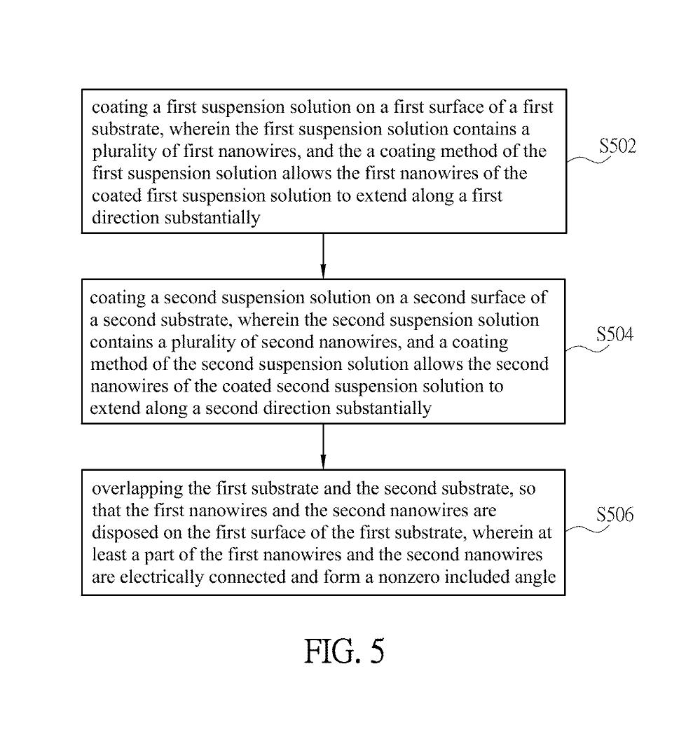

FIG. 5 is a flow chart of another manufacturing method of the conductive structure according to an embodiment of the invention. Referring to FIG. 5, the step S502 is to coat a first suspension solution on a first surface of a first substrate. The first suspension solution contains a plurality of first nanowires, and a coating method of the first suspension solution allows the first nanowires of the coated first suspension solution to extend along a first direction substantially. In addition, the step S504 is to coat a second suspension solution on a second surface of a second substrate. The second suspension solution contains a plurality of second nanowires, and a coating method of the second suspension solution allows the second nanowires of the coated second suspension solution to extend along a second direction substantially. In the step S506, the first substrate and the second substrate are overlapped, so that the first nanowires and the second nanowires are disposed on the first surface of the first substrate. Herein, at least a part of the first nanowires and the second nanowires are electrically connected and form a nonzero included angle. In brief, the manufacturing method of this embodiment is to coat the suspension solution on the surfaces of two substrates along a specific direction, and then bind the nanowires disposed on two surfaces. When binding the nanowires, the included angle between the first nanowires and the second nanowires is nonzero. As a result, the above mentioned conductive structure of the invention can be obtained.

In summary, to manufacturing the conductive structure of the invention, the suspension solution is coated along a specific direction by blade coating or bar coating and the coating speed is fixed, so that the nanowires in the suspension solution mostly extend along the same direction. Besides, it is possible to form two coatings in different directions on a single substrate, so that the manufactured conductive structure contains overlapped nanowires mainly in two directions. This configuration can form fewer nanowires in a unit area of the conductive structure, so that the conductive structure can have higher transparency and less raw material cost. Moreover, adding the conductive materials in the conductive structure can effectively reduce the junction resistance between the nanowires, thereby improving the conductivity thereof.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A conductive structure, comprising:
a plurality of first nanowires extending along a first direction substantially; and
a plurality of second nanowires extending along a second direction substantially, wherein at least a part of the second nanowires electrical connect to the first nanowires, and an included angle between the first direction and the second direction is nonzero.

2. The conductive structure of claim 1, wherein the nanowires are carbon nanotubes or metal nanowires.

3. The conductive structure of claim 1, further comprising:
a plurality of conductive materials disposed at junctions of parts of the first nanowires and the second nanowires, so that the first nanowires and the second nanowires are connected via the conductive materials.

4. The conductive structure of claim 3, wherein the conductive materials comprise ZnO.

5. A manufacturing method of a conductive structure, comprising steps of:
coating a first suspension solution on a surface of a substrate, wherein the first suspension solution contains a plurality of first nanowires, and a coating method of the first suspension solution allows the first nanowires of the coated first suspension solution to extend along a first direction substantially; and
coating a second suspension solution on the coated first suspension solution, wherein the second suspension solution contains a plurality of second nanowires, a coating method of the second suspension solution allows the second nanowires of the coated second suspension solution to extend along a second direction substantially, and at least a part of the second nanowires electrical connect to the first nanowires.

6. The manufacturing method of claim 5, wherein the first nanowires and the second nanowires are carbon nanotubes or metal nanowires.

7. The manufacturing method of claim 5, wherein the suspension solution is at least one of an ethanol solution and a water solution containing nanowires.

8. The manufacturing method of claim 5, wherein the coating method of the suspension solution comprises blade coating, bar coating, rod coating, or slot die coating.

9. The manufacturing method of claim 5, wherein the coating speed of the suspension solution is between 30 mm/s and 280 mm/s.

10. The manufacturing method of claim 5, further comprising a step of:
heating a substrate to evaporate the solvents of the suspension solutions.

11. The manufacturing method of claim 5, further comprising steps of:
coating a colloid suspension solution containing a plurality of conductive materials on the surface; and
annealing to form the conductive materials.

12. The manufacturing method of claim 11, wherein the conductive materials comprises ZnO.

13. A manufacturing method of a conductive structure, comprising steps of:
coating a first suspension solution on a first surface of a first substrate, wherein the first suspension solution contains a plurality of first nanowires, and the a coating method of the first suspension solution allows the first nanowires of the coated first suspension solution to extend along a first direction substantially;
coating a second suspension solution on a second surface of a second substrate, wherein the second suspension solution contains a plurality of second nanowires, and a coating method of the second suspension solution allows the second nanowires of the coated second suspension solution to extend along a second direction substantially; and
overlapping the first substrate and the second substrate, so that the first nanowires and the second nanowires are disposed on the first surface of the first substrate, wherein at least a part of the first nanowires and the second nanowires are electrically connected and form a nonzero included angle.
